(19) United States
(12) Patent Application Publication
(10) Pub. No.: US 2018/0226518 A1
(43) Pub. Date: Aug. 9, 2018

(54) METHOD OF MANUFACTURING AN OPTOELECTRONIC COMPONENT, AND OPTOELECTRONIC COMPONENT

(71) Applicant: OSRAM Opto Semiconductors GmbH, Regensburg (DE)

(72) Inventors: Reinhard Streitel, Laaber (DE); I-Hsin Lin-Lefebvre, Regensburg (DE); Chee Eng Ooi, Gelugor (MY); Ivan Galesic, Regensburg (DE)

(21) Appl. No.: 15/749,656

(22) PCT Filed: Aug. 2, 2016
(86) PCT No.: PCT/EP2016/068439

§ 371 Date: Feb. 1, 2018

(30) Foreign Application Priority Data
Aug. 6, 2015 (DE) 10 2015 112 967.1

(51) Int. Cl. H01L 31/0232; H01L 31/0203; H01L 33/48; H01L 33/46; H01L 31/14; H01L 33/62; H01L 31/02; H01L 31/0216; H01L 33/60; H01L 33/54

(52) U.S. Cl. CPC H01L 31/0232; H01L 31/0203; H01L 33/486; H01L 33/46; H01L 33/54; H01L 33/62; H01L 31/02005; H01L 31/02161; H01L 33/60; H01L 31/143

(57) ABSTRACT

A method of manufacturing an optoelectronic component includes providing a carrier; arranging an ink on an upper side of the carrier; arranging an adhesive on the ink; and arranging the optoelectronic semiconductor chip on the adhesive. An optoelectronic component includes a carrier, an ink arranged on an upper side of the carrier, an adhesive arranged on the ink, and an optoelectronic semiconductor chip arranged on the adhesive.

### TECHNICAL FIELD

This disclosure relates to a method of manufacturing an optoelectronic component, and an optoelectronic component.

### BACKGROUND

It is known to fasten semiconductor chips, for example, optoelectronic semiconductor chips on carriers, for example, on lead frames as an adhesive, for example, electrically conductive adhesive.

### SUMMARY

We provide a method of manufacturing an optoelectronic component including providing a carrier; arranging an ink on an upper side of the carrier; arranging an adhesive on the ink; and arranging the optoelectronic semiconductor chip on the adhesive.

We also provide an optoelectronic component including a carrier, an ink arranged on an upper side of the carrier, an adhesive arranged on the ink, and an optoelectronic semiconductor chip arranged on the adhesive.

### BRIEF DESCRIPTION OF THE DRAWINGS

FIG. 1 schematically shows a sectional side view of an optoelectronic component according to a first example.

FIG. 2 schematically shows a sectional side view of an optoelectronic component according to a second example.

FIG. 3 schematically shows a sectional side view of an optoelectronic component according to a third example.

FIG. 4 schematically shows a sectional side view of an optoelectronic component according to a fourth example.

FIG. 5 schematically shows a sectional side view of an optoelectronic component according to a fifth example.

### LIST OF REFERENCES

10 optoelectronic component

100 carrier

110 upper side

111 uncovered part of the upper side

120 coating

130 first section

140 second section

150 housing body

160 cavity

200 ink

210 layer thickness

300 adhesive

400 optoelectronic semiconductor chip

410 upper side

420 lower side

430 electrical contact pad

440 bonding wire

### DETAILED DESCRIPTION

Our method of manufacturing an optoelectronic component comprises steps of providing a carrier, arranging an ink on an upper side of the carrier, and fastening an optoelectronic semiconductor chip on the upper side of the carrier.

The ink arranged on the upper side of the carrier may be used to make the fastening of the optoelectronic semiconductor chip on the upper side of the carrier more robust and stable. To this end, the optoelectronic semiconductor chip is arranged over the ink. The optoelectronic semiconductor chip may in this case be fastened directly on the upper side of the carrier by the ink so that the method can be carried out particularly simply and economically. As an alternative, the optoelectronic semiconductor chip may be fastened on the ink by an adhesive. In this case, reliably adhering connections can respectively be provided between the upper side of the carrier and the ink, and between the ink and the adhesive. In addition, the ink may also prevent excessive flow of the adhesive.

By arranging the ink on the upper side of the carrier, in this method a fresh and uncontaminated surface can be provided on the upper side of the carrier. Elaborate cleaning steps, which may potentially damage the optoelectronic component obtainable by the method, can therefore advantageously be obviated in this method.

The ink arranged on the upper side of the carrier in this method may also be used to increase optical reflectivity of the upper side of the carrier. This may advantageously make it possible to use an inexpensive carrier without an optically reflective coating.

The ink may be electrically conductive. Advantageously, in the optoelectronic component obtainable by this method, the ink may therefore mediate an electrically conductive connection between the carrier and the optoelectronic semiconductor chip.

The optoelectronic semiconductor chip may be fastened on the ink. Advantageously, the ink may in this case mediate a more robust and mechanically more stable connection between the carrier the optoelectronic semiconductor chip, than would be possible without using the ink.

The fastening of the optoelectronic semiconductor chip may comprise steps of arranging an adhesive on the ink, and arranging the optoelectronic semiconductor chip on the adhesive. Advantageously, this method makes it possible to manufacture a mechanically robust connection both between the upper side of the carrier and the ink, and between the ink and the optoelectronic semiconductor chip fastened on the ink by the adhesive. In the optoelectronic component obtainable by the method, a robust and mechanically stable connection is thus obtained between the upper side of the carrier and the optoelectronic semiconductor chip. At the same time, excessive flow of the adhesive can be prevented by arranging the adhesive on the ink.

The optoelectronic semiconductor chip may be arranged directly on the ink. Advantageously, this method requires a particularly small number of individual processing steps, and can therefore be carried out particularly simply and economically. The ink may in this case allow reliable fastening of the optoelectronic semiconductor chip on the upper side of the carrier of the optoelectronic component obtainable by the method.

Arranging the ink may be carried out after fastening the optoelectronic semiconductor chip on the upper side of the carrier. In the optoelectronic component obtainable by this method, the ink may therefore provide protection of the upper side of the carrier against corrosion. In this case, for example, the ink may have a filler comprising nanoscale gold particles or corrosion-stable gold-coated particles.

The carrier may comprise an electrically insulating material, in particular a ceramic. In this method, for example, electrically conductive contact pads, connections or conductive tracks may be provided by virtue of the ink arranged on the upper side of the carrier.

The carrier may be configured as a lead frame and comprises an electrically conductive material, in particular copper. Advantageously, the method therefore makes it possible to manufacture a lead frame-based optoelectronic component.

The carrier may be provided having a coating arranged on its upper side, in particular having a coating comprising Ag, Au or NiPdAu. In this method, the ink may advantageously be used for improved adhesion of the optoelectronic semiconductor chip on the upper side of the carrier, improvement of the optical reflectivity of the upper side of the carrier, and/or protection of the upper side of the carrier against corrosion.

The carrier may be provided having a housing body in which the carrier is at least partially embedded. In this case, at least a part of the upper side of the carrier is not covered by the housing body. The ink is arranged on the uncovered part of the upper side of the carrier. Advantageously, this method can make it possible to use an inexpensive carrier without electrodeposited coating. In this case, the ink arranged on the upper side of the carrier in this method may provide mechanically stable fastening of the optoelectronic semiconductor chip on the upper side of the carrier, manufacturing of a reliable wire bond connection, an increase of optical reflectivity of the upper side of the carrier, corrosion protection of the upper side of the carrier, and/or further advantages.

The entire part of the upper side of the carrier not covered by the housing body may be covered by the ink. Advantageously, the method can therefore be carried out particularly simply, rapidly and economically. Furthermore, the full coverage of the part of the upper side of the carrier not covered by the housing body may advantageously provide an increase of the optical reflectivity of the upper side of the carrier, and/or protection of the upper side of the carrier against corrosion.

The ink may be arranged only on a limited section of the upper side of the carrier. In this way, in this method, the properties of the upper side of the carrier advantageously remain unchanged outside the limited section of the upper side of the carrier. If the upper side of the carrier already has a high optical reflectivity, for example, a decrease of the optical reflectivity is avoided by not covering the upper side of the carrier outside the limited section of the upper side of the carrier.

The ink may be arranged on the upper side of the carrier by a dosing method, inkjet printing (jetting), application with a pad (stamping) or a printing method, in particular screen printing. Advantageously, the arranging of the ink is therefore carried out by an established and highly controllable method. The aforementioned methods allow rapid and economical arranging of the ink on the upper side of the carrier. In this case, the methods make it possible to limit the arranging of the ink to limited sections of the upper side of the carrier.

The ink may comprise particles comprising a metal or an alloy, in particular particles comprising Ag and/or Au, in particular particles having a coating or no coating. Advantageously, the particles embedded in the ink make it possible to adapt the ink to special tasks to be fulfilled by the ink. The particles of the ink may fill indentations on the upper side of the carrier, thereby reducing the roughness of the upper side of the carrier, and thus improve the mechanical adhesion between the upper side of the carrier and the ink.

The particles may have an average size of 1 nm to 1000 nm. Advantageously, particles of this order of magnitude allow particularly effective reduction of the roughness of the upper side of the carrier.

The ink may comprise a filler. The filler may, for example, allow adaptation of a thermal expansion coefficient of the ink to a thermal expansion coefficient of the carrier, and/or to a thermal expansion coefficient of the optoelectronic semiconductor chip. For example, the filler contained in the ink may adapt the thermal expansion coefficient of the ink to a value lying between the values of the thermal expansion coefficients of the carrier and the optoelectronic semiconductor chip. The filler contained in the ink may also be used to increase or reduce a viscosity of the ink.

The ink may comprise a solvent with or without polymeric constituents. An ink comprising a solvent with polymeric constituents may in this case, for example, be suitable for the manufacture of an optoelectronic component which emits light with a wavelength of more than 800 nm. Inks comprising a solvent without polymeric constituents may be suitable for the manufacture of optoelectronic component which emit light with a wavelength in the visible and/or ultraviolet spectral range.

The ink may be applied as a layer with a layer thickness of 100 nm to 10 μm. In this case, thinner layers may suffice to increase the optical reflectivity, improve corrosion stability, and/or increase adhesion. Thicker layers may provide a reduction of the roughness of the upper side of the carrier.

An optoelectronic component comprises a carrier, an ink arranged on an upper side of the carrier, and an optoelectronic semiconductor chip arranged on the upper side of the carrier.

In this optoelectronic component, the ink arranged on the upper side of the carrier may advantageously increase optical reflectivity of the upper side of the carrier, improve a corrosion stability of the carrier, and/or improve mechanical stability of the connection between the optoelectronic semiconductor chip and the carrier.

The optoelectronic semiconductor chip may be fastened on the ink. Advantageously, the ink may therefore improve robustness and mechanical stability of the connection between the optoelectronic semiconductor chip and the upper side of the carrier of the optoelectronic component.

The above-described properties, features and advantages of our method, as well as the way in which they are achieved, will become more clearly and readily comprehensible in conjunction with the following description of the examples, which will be explained in more detail in connection with the drawings.

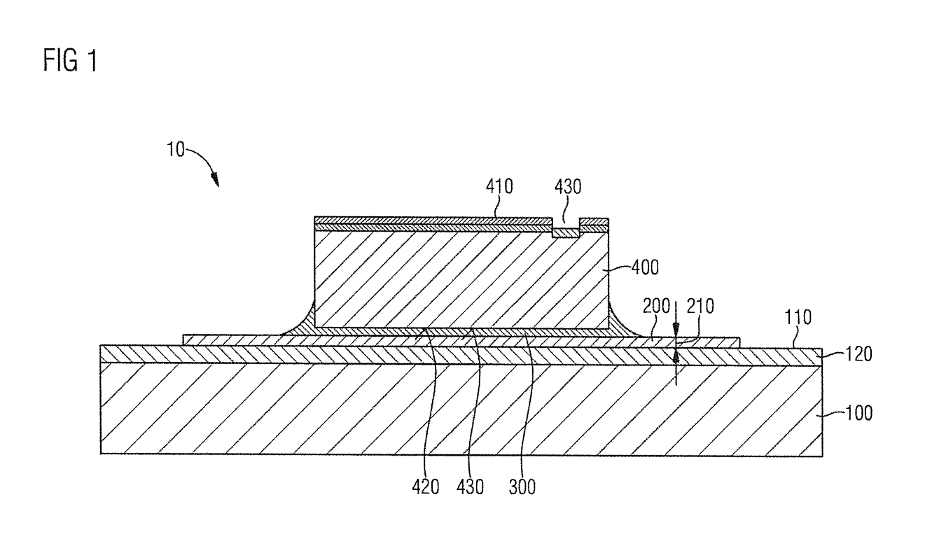

FIG. 1 shows a sectional side view of an optoelectronic component 10 according to a first example. The optoelectronic component 10 is configured to emit and/or detect electromagnetic radiation, for example, visible light. The optoelectronic component 10 may, for example, be a light-emitting diode component (LED component) or a laser component.

The optoelectronic component 10 comprises a carrier 100. In the example represented, the carrier 100 comprises an electrically conductive material, for example, copper. The carrier 100 may, for example, be configured as a lead frame.

On an upper side 110 of the carrier 100, the latter has a coating 120. The coating 120 may, for example, comprise silver (Ag), gold (Au) or an alloy, for example, NiPdAu. The coating 120 may, for example, be provided to increase an optical reflectivity of the upper side 110 of the carrier 100, and/or to facilitate fastening of an optoelectronic semiconductor chip and/or of a bonding wire on the upper side 110 of the carrier 100. The coating 120 may, for example, have been applied by an electrodeposition method.

A layer of an ink 200 has been arranged on the upper side 110 of the carrier 100, i.e., on the coating 120 of the carrier 100. The ink 200 may, for example, have been arranged on the upper side 110 of the carrier 100 by a dosing method, by inkjet printing (jetting), by application with a pad or by a printing method, in particular, for example, by screen printing.

The ink 200 is electrically conductive. The ink 200 comprises particles comprising a metal or an alloy. For example, the ink 200 may comprise particles comprising Ag, Au and/or an alloy of these metals. The particles of the ink 200 may optionally have a coating. The particles of the ink 200 may, for example, have an average size of 1 nm to 1000 nm.

The ink 200 arranged on the upper side 110 of the carrier 100 leads to smoothing of the upper side 110 of the carrier 100. The particles contained in the ink 200 can at least partially fill indentations and irregularities of the coating 120 on the upper side 110 of the carrier 100 so that reduction of the roughness of the upper side 110 of the carrier 100 and homogenization of the upper side 110 of the carrier 100 is achieved. The layer of the ink 200 may to this end have a layer thickness 210 which, for example, is between a few micrometers and a few tens of micrometers.

After the ink 200 has been arranged on the upper side 110 of the carrier 100, it may be cured. Curing the ink 200 may, for example, be carried out by a heat treatment or irradiation with light of an established wavelength, for example, irradiation with UV light.

Subsequently, an optoelectronic semiconductor chip 400 has been fastened on the upper side 110 of the carrier 100. The optoelectronic semiconductor chip 400 has in this case been fastened by an adhesive 300 on the ink 200 arranged on the upper side 110 of the carrier 100. The adhesive 300 has in this case first been arranged on the ink 200. Subsequently, the optoelectronic semiconductor chip 400 has been arranged on the adhesive 300. A further step of curing the adhesive 300 may then have been carried out. Curing the adhesive 300 may in this case, for example, have been carried out by a heat treatment or irradiation with light of an established wavelength, for example, by irradiation with UV light.

The optoelectronic semiconductor chip 400 is configured to emit or detect electromagnetic radiation, for example, visible light. The optoelectronic semiconductor chip 400 may, for example, be a light-emitting diode chip (LED chip) or a laser chip.

The optoelectronic semiconductor chip 400 has an upper side 410 and a lower side 420 lying opposite the upper side 410. The upper side 410 forms a radiation transmission surface of the optoelectronic semiconductor chip 400. If the optoelectronic semiconductor chip 400 is configured to detect electromagnetic radiation, the optoelectronic semiconductor chip 400 may detect radiation striking the upper side 410. If the optoelectronic semiconductor chip 400 is configured to emit electromagnetic radiation, electromagnetic radiation emitted by the optoelectronic semiconductor chip 400 is at least partially emitted on the upper side 410 of the optoelectronic semiconductor chip 400.

The optoelectronic semiconductor chip 400 has at least two electrical contact pads 430 that allow electrical contacting of the optoelectronic semiconductor chip 400. In the example shown in FIG. 1, one of the electrical contact pads 430 is configured on the upper side 410 and a further electrical contact pad 430 is configured on the lower side 420 of the optoelectronic semiconductor chip 400.

By virtue of the ink 200 arranged between the adhesive 300 and the upper side 110 of the carrier 100, improved adhesion of the optoelectronic semiconductor chip 400 on the upper side 110 of the carrier 100 is achieved. This is achieved on the one hand by a high adhesion between the ink 200 and the upper side 110 of the carrier 100, and on the other hand by a high adhesion between the ink 200 and the adhesive 300.

Good adhesion of the ink 200 on the upper side 110 of the carrier 100 results from a large contact area between the ink 200 and the upper side 110 of the carrier 100, which may in particular be larger than the area of the lower side 420 of the optoelectronic semiconductor chip 400.

The ink 200 furthermore comprises a solvent with or without polymeric constituents. Because of this solvent, impurities lying on the upper side 110 of the carrier 100 can be dissolved during application of the ink 200 onto the upper side 110 of the carrier 100 so that good adhesion of the ink 200 on the upper side 110 of the carrier 100 can be obtained. The solvent of the ink 200 may in particular comprise polymeric constituents, for example, silicones, epoxides or hybrid polymeric constituents, if the optoelectronic component 10 is intended to emit or detect electromagnetic radiation with a wavelength of more than 800 nm. If the optoelectronic component 10 is intended to emit or detect electromagnetic radiation with a wavelength of less than 800 nm, for example, to emit or detect visible light of UV light, then the solvent of the ink 200 should generally not comprise polymeric constituents.

A high adhesion between the ink 200 and the adhesive 300 is assisted by the fact that the ink 200 arranged on the upper side 110 of the carrier 100 can homogenize and smooth the upper side 110 of the carrier 100 by irregularities of the upper side 110 of the carrier 100 being compensated for at least partially by the ink 200. In this way, the wetting properties of the adhesive 300 on the layer of the ink 200 differ from those on the upper side 110 of the carrier 100.

It is possible not to arrange the ink 200 until shortly before fastening the optoelectronic semiconductor chip on the upper side 110 of the carrier 100, for example, only after a process step of embedding the carrier 100 in a plastic material forming a housing body and after a process step of removing residues of the plastic material (deflashing). In this case, the ink 200 covers impurities possibly arranged on the upper side 110 of the carrier 100 so that a fresh and uncontaminated surface is provided. If arranging the optoelectronic semiconductor chip 400 is then carried out shortly after arranging the ink 200, the surface provided by the ink 200 can still have a low degree of contamination so that good adhesion of the adhesive 300 on the ink 200 is made possible.

Because impurities possibly lying on the upper side 110 of the carrier 100 can be covered by the ink 200, it may be possible to omit a cleaning step of cleaning the upper side 110 of the carrier 100, which precedes arranging the ink 200.

The ink 200 arranged on the upper side 110 of the carrier 100 may also be used as a diffusion barrier for the material of the carrier 100. Furthermore, the ink 200 may prevent diffusion of contaminants.

The adhesive 300 may wet the ink 200 more strongly or less strongly than it wets the upper side 110 of the carrier 100 without the layer of the ink 200 arranged thereon having been wetted. By adapting the composition of the ink 200, the wetting properties of the adhesive 300 can be adapted in a desired way.

The ink 200 arranged between the upper side 110 of the carrier 100 and the adhesive 300 may prevent undesired flow or running of the adhesive 300. This may be assisted by a reduced surface energy of the ink 200 compared to the material of the carrier 100, or of the coating 120. The layer thickness 210 of the layer of the ink 200 may to this end, in particular, be 100 nm to a few micrometers.

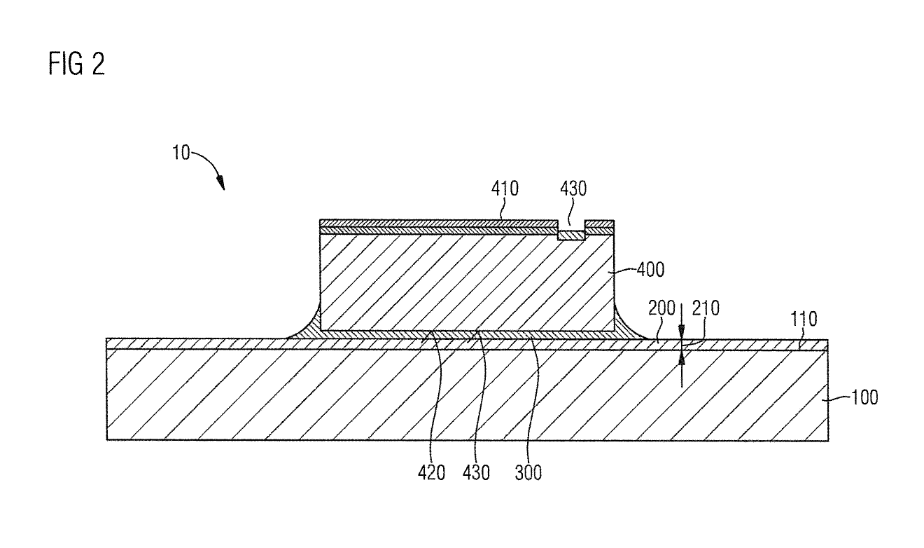

FIG. 2 shows a schematic sectional side view of an optoelectronic component 10 according to a second example. The example of the optoelectronic component 10 as represented in FIG. 2 has great similarities with the example of the optoelectronic component 10 as shown in FIG. 1. Corresponding component parts are provided with the same references in the two figures. Only the differences between the example represented in FIG. 2 and the example represented in FIG. 1 will be explained below. The example shown in FIG. 2 may be manufactured by the method described with the aid of FIG. 1, if the differences described below are taken into account.

In the example shown in FIG. 2, the upper side 110 of the carrier 100 does not have a coating. For this reason, in the example of the optoelectronic component 10 as represented in FIG. 2, the carrier 100 can be obtained particularly economically. The carrier 100 may in other regards comprise the same material as the example shown in FIG. 1, for example, copper.

Since the carrier 100 in the example shown in FIG. 2 does not have a coating on its upper side 110, fastening the optoelectronic semiconductor chip 400 by the adhesive 300 without the ink 200 arranged between the upper side 110 of the carrier 100 and the adhesive 300 would be unreliable and mechanically unstable. Because of the ink 200 arranged on the upper side 110 of the carrier 100, sufficiently stable fastening of the optoelectronic semiconductor chip 400 on the upper side 110 of the carrier 100 can be achieved. The layer thickness 210 of the layer of the ink 200 may to this end, for example, lie between a few micrometers and a few tens of micrometers.

In contrast to the example shown in FIG. 1, in the example represented in FIG. 2 the ink 200 covers the upper side 110 of the carrier 100 fully. It would, however, also be possible to cover only a part of the upper side 110 of the carrier 100 by the ink 200 in the example shown in FIG. 2 as well. It would likewise be possible to cover the upper side 110 of the carrier 100 fully with the ink 200 in the example shown in FIG. 1 as well.

Owing to the full covering of the upper side 110 of the carrier 100 by the ink 200, a corrosion susceptibility of the carrier 100 can be reduced in the example shown in FIG. 2. The ink 200 arranged on the upper side 110 of the carrier 100 protects the carrier 100 against corrosion by external effects. To this end, the layer thickness 210 of the layer of the ink 200 may, for example, be 100 nm to a few micrometers. The ink 200 may in this case, for example, comprise embedded particles having a coating. The embedded particles may have an average size of 1 nm to 1000 nm.

The carrier 100 of the optoelectronic component 10 of the example represented in FIG. 2 may, in a subsequent processing step, be embedded at least partially in a plastic material forming a housing body. In this case, the ink 200 arranged on the upper side 110 of the carrier 100 may improve adhesion of the plastic material on the upper side 110 of the carrier 100. Fastening the optoelectronic semiconductor chip 400 on the upper side 110 of the carrier 100 may in this case also not be carried out until after the embedding of the carrier 100 in the plastic material.

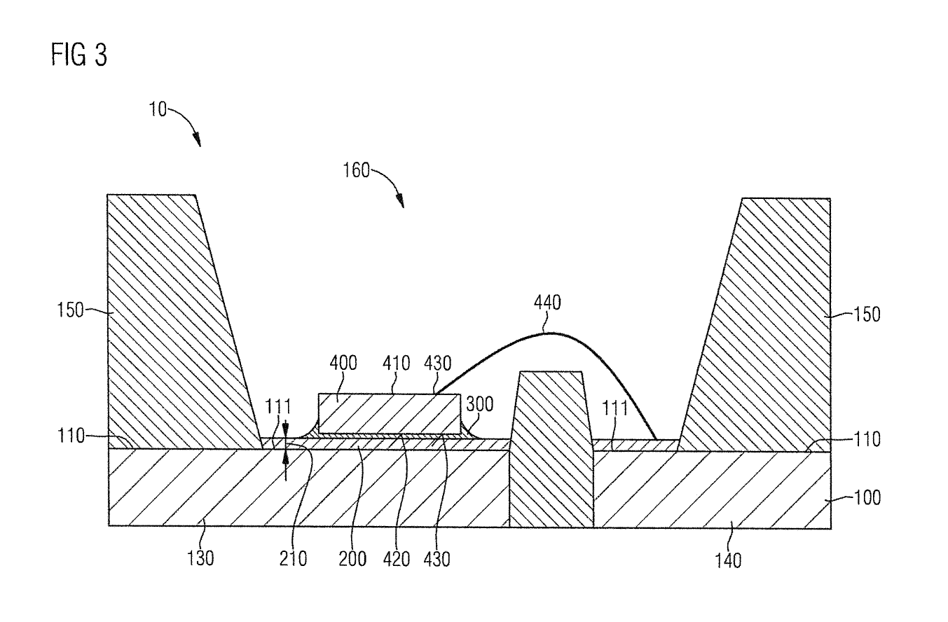

FIG. 3 shows a schematic sectional side view of an optoelectronic component 10 according to a third example. The example of the optoelectronic component 10 as represented in FIG. 3 has great similarities with the examples shown in FIGS. 1 and 2. Corresponding component parts are provided with the same references in FIG. 3 as in FIGS. 1 and 2. Only the differences between the individual examples and the associated manufacturing methods will be described below.

In the example shown in FIG. 3, the carrier 100 comprises a first section 130 and a second section 140. The carrier 100 may in this case be configured as a lead frame. The first section 130 and the second section 140 are in this case lead frame sections of the carrier 100 configured as a lead frame. The first section 130 and the second section 140 are arranged next to one another and at a distance from one another in a common plane. In this case, the first section 130 and the second section 140 are electrically insulated from one another.

In the example represented in FIG. 3, the carrier 100 does not have a coating on its upper side 110. It would, however, be possible to provide a coating on the upper side 110 of the carrier 100 in the example shown in FIG. 3 as well.

In the example shown in FIG. 3, the optoelectronic component 10 comprises a housing body 150. In this case, the carrier 100 is at least partially embedded in the housing body 150. The housing body 150 may, for example, comprise a plastic material, and have been configured, for example, by a molding method. In this case, the carrier 100 may already have been embedded in the housing body 150 during the manufacturing of the housing body 150, by the material of the housing body 150 being molded around the carrier 100.

The upper side 110 of the carrier 100 is only partially covered by the material of the housing body 150. The housing body 150 comprises a cavity 160. In the region of the cavity 160, a part 111 of the upper side 110 of the carrier 100 not covered by the material of the housing body 150 is exposed. The uncovered part 111 in this case comprises parts of the upper side 110 both of the first section 130 and of the second section 140 of the carrier 100.

In the example of the optoelectronic component 10 as shown in FIG. 3, the ink 200 is arranged on the uncovered part 111 of the upper side 110 of the carrier 100. The entire part 111 of the upper side 110 of the carrier 100 which is not covered by the housing body 150 is in this case covered by the ink 200. Arranging the ink 200 on the uncovered part 111 of the upper side 110 of the carrier 100 may, for example, be carried out after embedding the carrier 100 in the housing body 150.

The parts of the upper side 110 of the carrier 100 covered by the housing body 150 are not covered by the ink 200 in the example of the optoelectronic component 10 as shown in FIG. 3. It would, however, also be possible to arrange the ink 200 on the upper side 110 of the carrier 100 already before embedding the carrier 100 in the housing body 150. In this case, the ink 200 may extend over those parts of the upper side 110 of the carrier 100 subsequently covered by the material of the housing body 150. In these parts of the upper side 110 of the carrier 100, the ink 200 may ensure particularly reliable adhesion of the material of the housing body 150 on the upper side 110 of the carrier 100.

In the example of the optoelectronic component 10 as shown in FIG. 3, the optoelectronic semiconductor chip 400 is fastened by the adhesive 300 on the ink 200 on the upper side 110 of the first section 130 of the carrier 100. Fastening the optoelectronic semiconductor chip 400 has been carried out after arranging the ink 200 on the upper side 110 of the carrier 100. Because of the ink 200 arranged between the adhesive 300 and the upper side 110 of the carrier 100, there is good adhesion between the optoelectronic semiconductor chip 400 and the upper side 110 of the carrier 100.

The ink 200 and the adhesive 300 are each configured to be electrically conductive in the example of the optoelectronic component 10 as shown in FIG. 3. Because of this, the electrical contact pad 430 of the optoelectronic semiconductor chip 400 configured on the lower side 420 of the optoelectronic semiconductor chip 400 electrically conductively connects to the first section 130 of the carrier 100.

In the example of the optoelectronic component 10 as shown in FIG. 3, the electrical contact pad 430 of the optoelectronic semiconductor chip 400 configured on the upper side 410 of the optoelectronic semiconductor chip 400 electrically conductively connects via a bonding wire 440 to the second section 140 of the carrier 100. To this end, the bonding wire 440 connects to the electrical contact pad 430 configured on the upper side 410 of the optoelectronic semiconductor chip 400 and to the ink 200 on the upper side 110 of the second section 140 of the carrier 100. Reliable fastening of the bonding wire 440 on the second section 140 of the carrier 100 is assisted by the ink 200 arranged on the upper side 110 of the second section 140 of the carrier 100. It would, however, also be possible to omit the provision of the ink 200 on the upper side 110 of the second section 140 of the carrier 100. This is the case in particular when the carrier 100 has, at least in the second section 140 on its surface 110, a coating allowing simple and durable fastening of bonding wires.

In the example of the optoelectronic component 10 as shown in FIG. 3, the electrical contact pads 430 of the optoelectronic semiconductor chip 400 are therefore connected electrically conductively to the first section 130 and the second section 140 of the carrier 100. This makes it possible to electrically contact the optoelectronic semiconductor chip 400 of the optoelectronic component 10 via the first section 130 and the second section 140 of the carrier. The optoelectronic component 10 may, for example, be provided as an SMT component for surface mounting, for example, for surface mounting by reflow soldering.

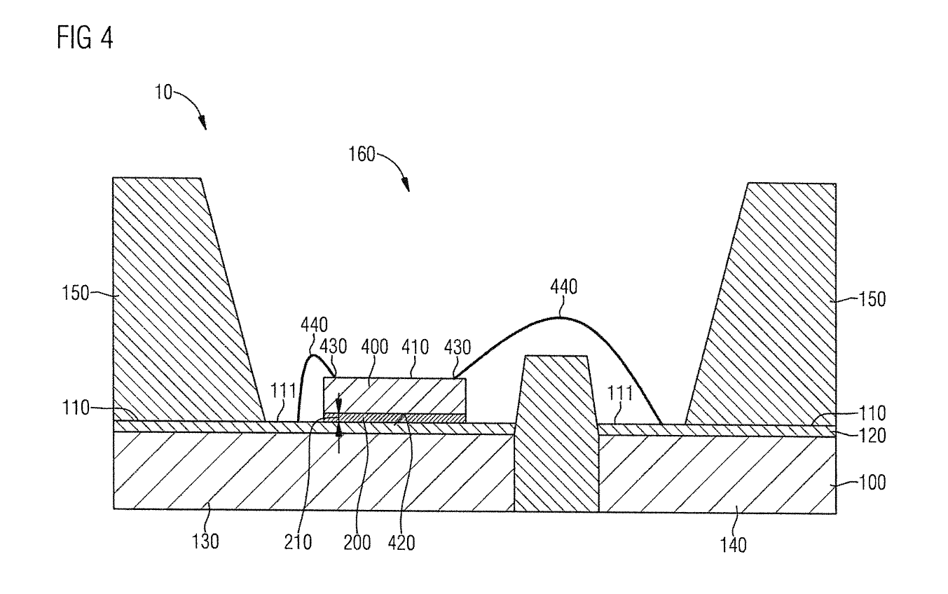

FIG. 4 shows a schematic sectional side view of an optoelectronic component 10 according to a fourth example. The example of the optoelectronic component 10 as shown in FIG. 4 has great similarities with the example of the optoelectronic component 10 as shown in FIG. 3. Corresponding component parts are provided with the same references in FIGS. 3 and 4. Only the way in which the examples of the optoelectronic component 10 shown in FIGS. 3 and 4 and the respective manufacturing methods differ will be described below.

In the example of the optoelectronic component 10 as shown in FIG. 4, the carrier 100 has a coating 120 on its upper side 110, as in the example represented in FIG. 1. The carrier 100 and its coating 120 are configured to be electrically conductive. The coating 120 may be intended to increase an optical reflectivity of the upper side 110 of the carrier 100, to increase a corrosion stability of the carrier 100, and/or to facilitate the fastening of the bonding wire 440. The coating 120 could, however, also be omitted in the example of the optoelectronic component 10 as shown in FIG. 4.

In the example of the optoelectronic component 10 as shown in FIG. 4, the ink 200 covers only a limited section of the part 111 of the upper side 110 of the carrier 100 not covered by the material of the housing body 150 in the first section 130 of the carrier 100. No ink 200 is arranged on the upper side 110 of the second section 140 of the carrier 100. The layer of the ink 200 arranged on the upper side 110 of the first section 130 of the carrier 100 has, in plan view of the upper side 110 of the carrier 100, an area only slightly greater than the area of the lower side 420 of the optoelectronic semiconductor chip 400.

In plan view of the upper side 110 of the carrier 100, the layer of the ink 200 may, for example, have an approximately circular disk-shaped or elliptical shape, an approximately rectangular shape or another shape. A geometry of the layer of the ink 200 differing from an approximately circular disk-shaped or elliptical shape may, in particular, be obtained when the ink 200 has a high viscosity when the ink is arranged on the upper side 110 of the carrier 100.

Because the ink 200 covers only a limited section of the upper side 110 of the carrier 100 in the example of the optoelectronic component 10 as shown in FIG. 4, a possible high optical reflectivity of the upper side 110 of the carrier 100 due to the coating 120 of the carrier 100 can be reduced only to a small extent by the ink 200. The sections of the upper side 110 of the carrier 100 not covered by the ink 200 have the high optical reflectivity due to the coating 120.

It is possible to arrange the ink 200 on the entire uncovered part 111 of the upper side 110 of the carrier 100, or even on the entire upper side 110 of the carrier 100, in the example of the optoelectronic component 10 as shown in FIG. 4 as well. It is likewise possible to arrange the ink only on the upper side 110 of the first section 130 or of the second section 140 of the carrier 100.

In the example of the optoelectronic component 10 as shown in FIG. 4, the optoelectronic semiconductor chip 400 is arranged directly on the ink 200 and fastened on the upper side 110 of the carrier 100 by the ink 200. No additional adhesive is therefore provided between the ink 200 and the lower side 420 of the optoelectronic semiconductor chip 400. The optoelectronic component 10 of the example shown in FIG. 4 can therefore be manufactured particularly simply and economically.

To manufacture the example of the optoelectronic component 10 as shown in FIG. 4, the optoelectronic semiconductor chip 400 may be arranged on the ink 200 immediately after the ink 200 is arranged on the upper side 110 of the carrier 100. Only then is the ink 200 cured.

In the example of the optoelectronic component 10 as shown in FIG. 4, the ink 200 may comprise a filler which may, for example, be intended to allow a high layer thickness 210 of the ink 200. The filler may also be intended to adapt a thermal expansion coefficient of the ink 200 to a desired value, for example, to a value lying between the thermal expansion coefficients of the carrier 100 and the optoelectronic semiconductor chip 400. The filler may, for example, be embedded in the ink 200 in the form of small spheres. The filler may, for example, comprise SiO₂ or TiO₂.

As an alternative, in the example of the optoelectronic component 10 as shown in FIG. 4 as well, it is possible to fasten the optoelectronic semiconductor chip 400 on the ink 200 on the upper side 110 of the carrier 100 by an adhesive.

In the example of the optoelectronic component 10 as shown in FIG. 4, both the electrical contact pads 430 of the optoelectronic semiconductor chip 400 are configured on the upper side 410 of the optoelectronic semiconductor chip 400. The optoelectronic semiconductor chip 400 may, for example, be configured as a flip-chip. The two electrical contact pads 430 of the optoelectronic semiconductor chip 400 electrically conductively connect via two bonding wires 440 to the first section 130 and the second section 140 of the carrier 100. The bonding wires 440 in this case connect to sections of the upper side 110 of the carrier 100 on which no ink 200 is arranged. This is facilitated by coating 120 of the carrier 100. Of course, it would however also be possible to connect the bonding wires 440 to parts of the upper side 110 of the first section 130 and the second section 140 of the carrier 100 covered by the ink 200.

In the example of the optoelectronic component 10 as shown in FIG. 4, there does not need to be an electrically conductive connection between the lower side 420 of the optoelectronic semiconductor chip 400 and the carrier 100. The ink 200 may therefore be configured to be electrically nonconductive in the example of the optoelectronic component 10 as shown in FIG. 4. If, other than as represented in FIG. 4, the optoelectronic semiconductor chip 400 connects to the ink 200 by an adhesive, as an alternative or in addition the adhesive may be configured to be electrically nonconductive.

In the example of the optoelectronic component 10 as shown in FIG. 4, the optoelectronic semiconductor chip 400 may also be configured as in the example of the optoelectronic component 10 as shown in FIG. 3, and electrically conductively connect to the carrier 100 in the manner represented in FIG. 3.

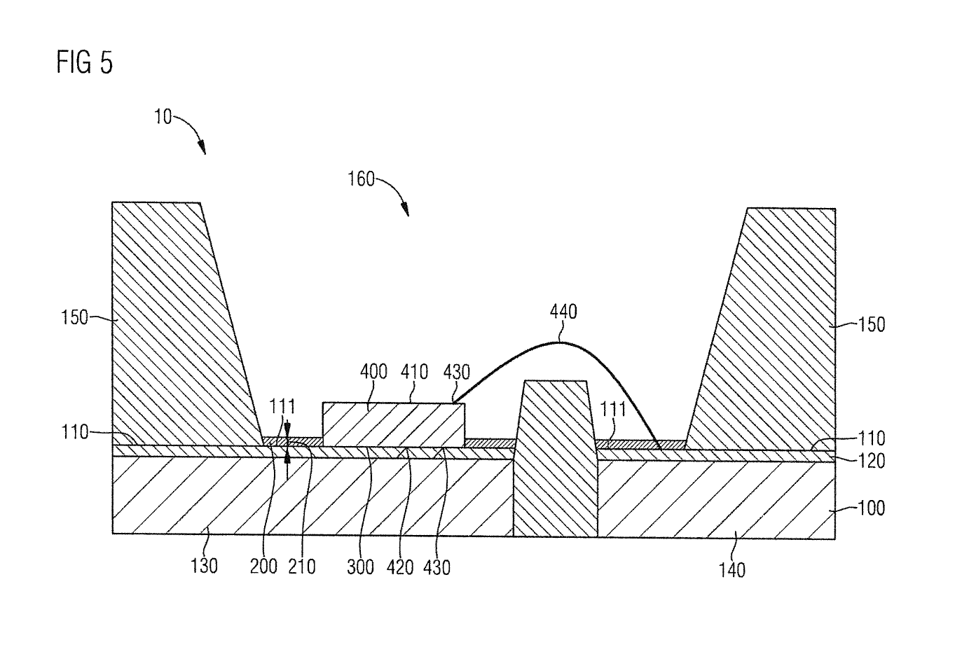

FIG. 5 shows a schematic sectional side view of an optoelectronic component 10 according to a fifth example. The fifth example of the optoelectronic component 10 as shown in FIG. 5 has great similarities with the example represented in FIG. 3. Corresponding component parts are provided with the same references in FIG. 5 as in FIG. 3. Only the differences between the various examples and the differences between the respective manufacturing methods will be described below.

In the example of the optoelectronic component 10 as shown in FIG. 5, the carrier 100 has a coating 120 on its upper side 110, as is also the case in the example shown in FIG. 4.

In the example of the optoelectronic component 10 as shown in FIG. 5, the optoelectronic semiconductor chip 400 has been fastened directly on the upper side 110 of the carrier 100 by the adhesive 300. No ink is therefore arranged between the adhesive 300 and the upper side 110 of the carrier 100. The adhesive 300 is electrically conductive, and produces an electrically conductive connection between the electrical contact pad 430 configured on the lower side 420 of the optoelectronic semiconductor chip 400 and the first section 130 of the carrier 100.

The electrical contact pad 430 of the optoelectronic semiconductor chip 400, which is configured on the upper side 410 of the optoelectronic semiconductor chip 400, electrically conductively connects via the bonding wire 440 to the second section 140 of the carrier 100. In this case, the bonding wire 440 is fastened directly on the upper side 110 of the second section 140 of the carrier 100, and not on a layer of ink arranged on the upper side 110 of the carrier 100.

To manufacture the optoelectronic component 10 of the example shown in FIG. 5, the ink 200 is not arranged on the upper side 110 of the carrier 100 until after the optoelectronic semiconductor chip 400 is fastened on the upper side 110 of the carrier 100. In this case, the ink 200 is arranged in all regions of the part 111 of the upper side 110 of the carrier 100 not covered by the housing body 150 and not covered by the optoelectronic semiconductor chip 400.

In the example of the optoelectronic component 10 as represented in FIG. 5, the ink 200 may be configured to be electrically conductive or electrically nonconductive and may, for example, comprise particles of gold or silver coated with gold. The ink 200 may be used to protect the upper side 110 of the carrier 100 against corrosion. As an alternative or in addition, the ink 200 may be used to increase an optical reflectivity of the upper side 110 of the carrier 100.

In another example (not represented) of the optoelectronic component 10, the carrier 100 comprises an electrically insulating material, for example, a ceramic. In this example, the ink 200 arranged on the upper side 110 of the carrier 100 may be configured to be electrically conductive and used to provide electrical contact pads and/or electrically conductive connections on the upper side 110 of the carrier 100.

Our methods and components have been illustrated and described in detail with the aid of the preferred examples. This disclosure is not, however, restricted to the examples disclosed. Rather, other variants may be derived therefrom by those skilled in the art, without departing from the protective scope of the appended claims.

This application claims priority of DE 10 2015 112 967.1, the subject matter of which is incorporated herein by reference.

1-20. (canceled)

21. A method of manufacturing an optoelectronic component comprising:
providing a carrier;
arranging an ink on an upper side of the carrier;
arranging an adhesive on the ink; and
arranging the optoelectronic semiconductor chip on the adhesive.

22. The method according to claim 21, wherein the ink is electrically conductive.

23. The method according to claim 21, wherein the carrier comprises an electrically insulating material or a ceramic.

24. The method according to claim 21, wherein the carrier is configured as a lead frame and comprises an electrically conductive material or copper.

25. The method according to claim 24, wherein the carrier is provided having a coating arranged at its upper side, the coating optionally comprising Ag, Au or NiPdAu.

26. The method according to claim 21,
wherein the carrier is provided having a housing body in which the carrier is at least partially embedded,
at least a part of the upper side of the carrier is not covered by the housing body, and
the ink is arranged on the uncovered part of the upper side of the carrier.

27. The method according to claim 26, wherein the entire part of the upper side of the carrier not covered by the housing body is covered by the ink.

28. The method according to claim 21, wherein the ink is arranged only on a limited section of the upper side of the carrier.

29. The method according to claim 21, wherein the ink is arranged at the upper side of the carrier by a dosing method, inkjet printing, stamping, a printing method or screen printing.

30. The method according to claim 21, wherein the ink comprises particles comprising a metal or an alloy, the particles optionally comprising Ag and/or Au, and the particles having a coating or have no coating.

31. The method according to claim 30, wherein the particles have an average size of 1 nm to 1000 nm.

32. The method according to claim 21, wherein the ink comprises a filler.

33. The method according to claim 21, wherein the ink comprises a solvent with or without polymeric constituents.

34. The method according to claim 21, wherein the ink is applied as a layer with a layer thickness of 100 nm to 10 μm.

35. An optoelectronic component comprising:
a carrier,
an ink arranged on an upper side of the carrier,
an adhesive arranged on the ink, and
an optoelectronic semiconductor chip arranged on the adhesive.
